(19) United States
(12) Patent Application Publication
(10) Pub. No.: US 2002/0075734 A1
(43) Pub. Date: Jun. 20, 2002

(54) Digital memory structure and device, and methods for the management thereof

(76) Inventors: James Ian Munro, Waterloo (CA); Andrej Brodnik, Ljubljana (SI); Svante Carlsson, Karlskrona (SE)

Correspondence Address: Steven S. Payne, 8027 Iliff Drive, Dunn Loring, VA, 22027, US

(21) Appl. No.: 09/863,313

(22) Filed: May 24, 2001

(30) Foreign Application Priority Data
Nov. 24, 1998 (SE) 9804033-0

(51) Int. Cl. G11C 29/00

(52) U.S. Cl. 365/200

(57) ABSTRACT

A digital memory structure manages a subset N of a universe U={0 . . . .M-1 } of elements e, where the universe U is represented by a complete binary tree of height m+1 with elements e of the universe U at its leaves. The digital memory structure has an array of overlapped registers reg[i], preferably where O i M/2-1, for storing internal nodes of the binary tree along respective paths from ancestors of the leaves to root. Location j of register reg[i] is arranged to store internal node k, preferably where k=(i div 2ⱼ)+2ₘ₋ⱼ₋ₗ). Any internal node of the binary tree is stored tagged, if the right and/or left subtree thereof contain(s) at least one element of subset N. The digital memory structure also has an array of pointers internal[l], preferably where 1 1 M-1, to the smallest element in the right subtree, and/or the largest element in the left subtree, of each respective ontemal node 1.

### TECHNICAL FIELD

The present invention relates to a digital memory structure for managing a subset of a universe of elements, including insertions and deletions of elements into/from said subset. The invention also relates to a digital memory device for implementing the digital memory structure.

### BACKGROUND ART

The so-called closest neighbour problem has several applications in the field of computers and computing. For instance, multiprocessing operating systems generally handle the scheduling of execution of program processes or jobs by a priority queue, in which individual processes are given respective positions depending on individual priority level, call for I/O interrupts, etc. The operating system uses the priority queue to decide which process to execute next, for instance the first process in the priority queue. The priority queue has to be dynamic, i.e. allow insertions and deletions of processes.

The so-called union-split-find problem is another example of a dynamic closest neighbour problem.

Unless the universe of elements, in which the dynamic closest neighbour problem is applied, is quite limited, prior art solutions have failed to provide limited response times for queries as well as updates. For instance, according to one previously known approach, if each element in the universe knows its closest neighbour, constant query response time is easily obtained, but updates are time consuming. This approach may be very attractive, when there are only a few updates, and is clearly helpful if there are none. A different approach is to note the presence or absence of a value in a small number of places (a bit map is the extreme), but this makes queries very costly.

### SUMMARY OF THE INVENTION

It is an object of the present invention to provide a constant time solution to the dynamic closest neighbour problem, for queries as well as updates. More specifically, it is an object of the present invention to provide a digital memory structure and device for allowing such constant time operations in a computerized environment.

These objects are achieved by a digital memory structure, a digital memory device and related methods according to the accompanying independent claims.

Further objects, advantages and features of the present invention appear from the following description as well as from the subclaims and the attached drawings.

### BRIEF DESCRIPTION OF THE DRAWINGS

The present invention will now be described in more detail, reference being made to the accompanying drawings, in which

FIGS. 1-6 are binary tree representations for illustrating various aspects of the present invention, and

FIG. 7 is a schematic block diagram representing a digital memory device according to the invention.

### DETAILED DISCLOSURE

A. Definitions

Definition 1a: Let N be a subset of elements of the universe U={O . . . M-1}. Then the one-dimensional dynamic closest neighbour (neighbourhood) problem is to support the following operations efficiently:

Insert (e), which inserts element e into the subset N.

Delete (e), which deletes element e from the subset N.

Left (e) (Right (e)), which returns the largest (smallest) element of N smaller (larger) than e. If such an element does not exist, −∞ (+∞) is returned.

To be able to talk also about both neighbours of the largest and the smallest element in N, we augment U by −∞ and +∞. Consequently, the right (left) neighbour of −∞ (+∞) is the smallest (largest) element in N.

Definition 1b: In the union-split-find, or interval sets, problem we have a set of contiguous and pairwise disjoint interval sets taken from a bounded universe. The interval I is identified by its minimum element:, min (I) The following operations are to be supported:

Find (e), which returns min (I), where e ε I,

Split (e) , which splits the interval I (e ε I) into consecutive intervals I₁ and I₂ such that min(I₁)=min (I) and min(I₂)=e, and

Merge (I), which puts elements from intervals I (e ε I) and I₁ ((e−1) ε I₁) into the interval I₂. Obviously, min(I₂)=min(I₁).

Since an interval is identified by its smallest element, we can replace the set of intervals with the set of these 25 smallest elements. This makes the union-split-find and neighbourhood problems equivalent as shown in Table 1.

TABLE 1
A mapping between the neighbourhood and interval
sets problems.

| neighbourhood | <=> | interval sets |
|---|---|---|
| Insert (e) | <=> | Split (e) |
| Delete (I) | <=> | Merge (I) |
| Left (e) | <=> | Find (e) |

Definition 1c: In the priority queue problem we have a set of elements, N, from a bounded universe and the following operations:

Insert (e), which inserts an element e into N.

DeleteMin, which deletes the smallest element from N and returns it,

ChangePriority (e, Δ), which changes the value of the element e in N for Δ,

Delete (e), which deletes an element e from N, and

MinPriority, which returns the smallest element in N.

As presented in Table 2 below, priority queue operations can be efficiently emulated by the operations of the neighbourhood problem. Thus, the priority queue problem is no harder than the neighbourhood problem. However, it is not known to be easier. In summary, a solution of a neighbourhood problem gives us also solutions for the union-split-find and the priority queue problems with the same time and space bounds.

TABLE 2
A mapping of the priority queue problem onto the
neighbourhood problem.

| priority queue | => | neighbourhood |
|---|---|---|
| Insert (e) | => | Insert (e) |
| DeleteMin | => | tmp: = Right (−∞); Delete (tmp); |
| | | return tmp |
| ChangePriority (e, Δ) | => | Delete (e); Insert (e + Δ) |
| Delete (e) | => | Delete (e) |
| MinPriority | => | Right (−∞) |

For the following discussion we study a complete binary tree (trie) 100 as shown in FIG. 1 with the elements 110 of U at the leaves of the tree and those leaves 120 representing the elements of N joined in a doubly linked list 130. We tag each node 140 that is a root of a subtree containing an element of N (including leaves in N). Furthermore, each tagged internal node has a pointer to the largest and smallest elements of N in its subtree.

To find either neighbour of any element e ε U, it is sufficient to find the other, as the desired value can be reached following pointers at the leaves. An approach to locating one of e's neighbours is to find the lowest tagged node on the path from the leaf e to the root. A linear scan does this in O(log M) time. Alternatively, it can be done using binary search with O(log M) worst case running time.

Summarizing the description above, we define: Definition 2: A simple tagged tree is a complete binary tree with elements of U at its leaves and

(i.) each node that is the root of a subtree containing an element of N is tagged,

(ii.) each internal tagged node has a pointer to the largest and smallest elements of N in its subtree, and

(iii.) elements of N are connected in a doubly linked list.

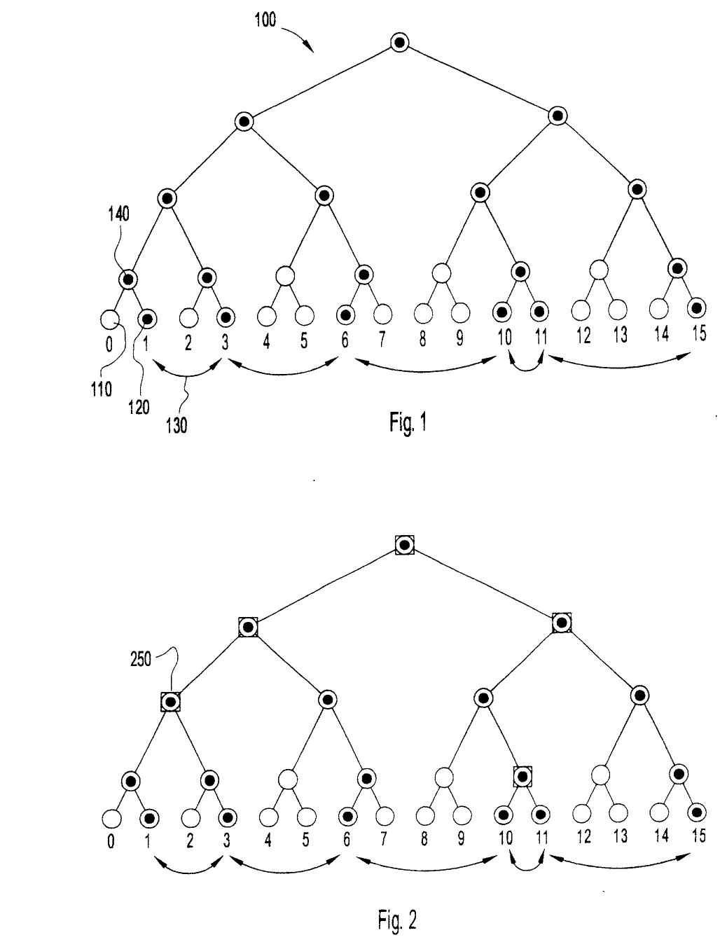

The neighbours of an element in a simple tagged tree are easily found in constant time, once the lowest tagged ancestor of the query point is found. The difficulty is that a single element of N may be referred to by up to lg M internal nodes. This would appear to impose a Ω(lg M) bound on any update algorithm. A simple modification of the structure to remove a multiple reference problem begins with the idea of a splitting node (see boxed nodes 250 in FIG. 2).

Definition 3: An internal node is a splitting node if there is at least one element of N in each of its subtrees.

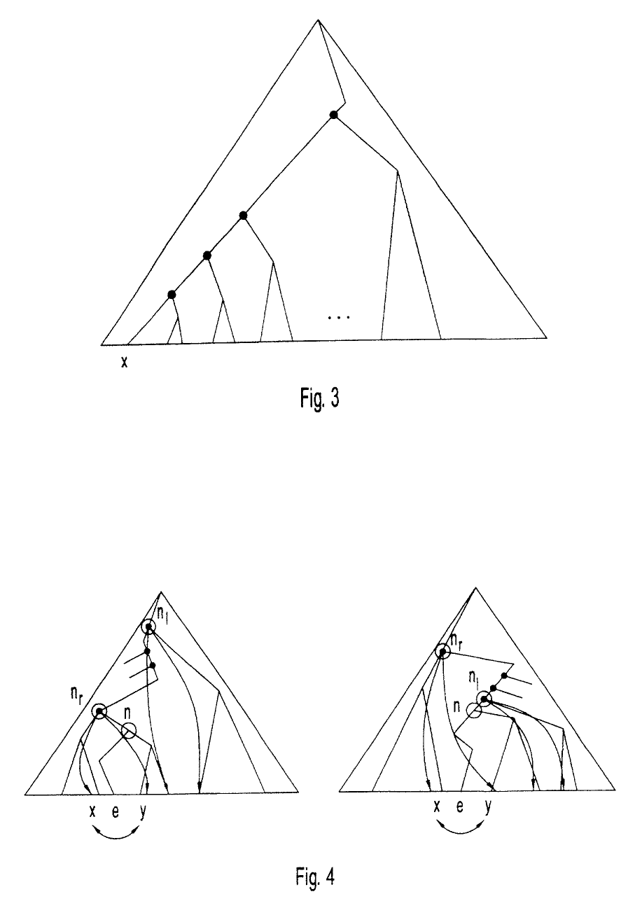

We now maintain tags and pointers only at splitting nodes. This does not quite solve the problem as a single element x of N may still be the smallest (largest) in up to lg M subtrees (see FIG. 3). The final twist is to maintain references to the leftmost (smallest) element in the right subtree and the rightmost (largest) element in the left subtree. That is to the “inside” rather than “outside” descendents. Thus, we have:

Definition 4: A split tagged tree is a complete binary tree on U in which:

(i.) a splitting node of the tree has a tag and pointers to the largest element in its left subtree and the smallest element in its right subtree,

(ii.) each leaf representing an element from N is tagged, and

(iii.) the elements of N are connected in a doubly linked list.

We will now show that a split tagged tree supports both constant time updates and constant time queries. To simplify further discussion, we introduce the following terms:

Definition 5: The lowest common node (or lowest common ancestor) of two leaves is the root of the smallest subtree containing both leaves.

Definition 6 The node n is a left (right) splitting node of e, if e is a leaf in the left (right) subtree of n. The first left (right) splitting node on a path from e to the root is the lowest left (right) splitting node of e.

To permit constant time updates only a few splitting nodes may have references to a given element in N. In fact, there are at most two such nodes:

Lema 1: Consider a split tagged tree, a tagged leaf e, and all left (right) subtrees at splitting nodes of the tree. Then e is the largest (smallest) element in the left (right) subtree of e's lowest left (right) splitting node, and in no other subtree rooted at a splitting node.

Proof: We prove only half of the lemma, since the other half is symmetrical. First, if e is the smallest element in N, then it has no left splitting node. Next, if n is e's right splitting node, then e is larger than any element in the left subtree of n. Since, by Definition 6, the lowest left splitting node n₁ is the first left splitting node on the path from e to the root, all other elements in the left subtree of n₁ are smaller than e. Finally, assume e is also the largest element in the left subtree of the left splitting node n₁. Since n₁ is e's left splitting node, there is an element, f, in the right subtree of n₁ and e <f. By Definition 6 n₁ is above n₁, and thus e and f are both in the left subtree of n₁. However, this contradicts the assumption that e is the largest element in the left subtree of n_{1.}

Finally, the following lemma indicates how to answer queries quickly:

Lemma 2: Let n₁ and nᵣ be e's lowest left and right splitting nodes, respectively, and let x, y ε N be the neighbours of e, where x <e <y. Then, if e ∉ N either the pointers at n₁ or at nr point to x and y; and if e ε N then the pointers at nᵣ refer to x and e, and those at n₁ refer to e and y.

Proof: If e ε N, this lemma follows from Lemma 1. If e ∉ N, FIG. 4 presents two of four possible situations (the other two are symmetrical). Let n_{c} be the lowest common node of x and y. By definition, it is also a splitting node, and moreover, it is a splitting node on a path from e to the root. Since x and y are e's neighbours, they are each other's neighbours in N, and therefore x is the largest element in n_{c}'s left subtree and y the smallest element in n_{c}'s right subtree. Consequently, the pointers at n_{c} point to x and y, e's neighbours. A contradiction argument similar to that of the proof of Lemma 1 shows that n_{c} is either n₁ or n_{r.}

B. Preferred Embodiment

To solve the dynamic one-dimensional closest neighbour problem, we first describe a digital data structure and how it is stored in a digital memory device, and then give a set of algorithms.

The data structure is a split tagged tree, from Definition 4, with the nodes represented in an array in standard heap order, i.e. the root is n₁, n₂ and n₃ are its left and right child respectively. In general, node n₁ has left and right children n₂, and n_{21+1.}

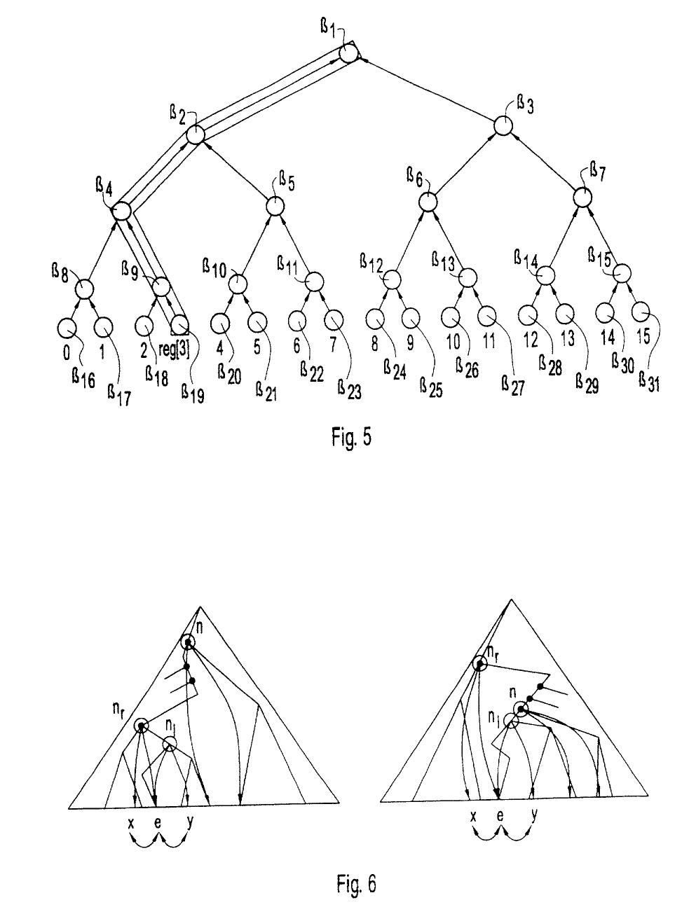

To store this data structure, we divide a passive memory block into an overlapped and a non-overlapped (conventional) part. The graph describing the overlapped part is a complete binary tree of height m (it is a level shorter than the split tagged tree), where the registers are represented by paths from leaves to the root (cf. FIG. 5). Thus, the leaves are not shared and appear in the least significant position of individual registers, while the root, which is shared by all registers, appears in the most significant position of registers. The bits of the overlapped memory, βᵢ, where 1≦i <2^{m}=M, are enumerated in standard heap order as well. Hence,

reg[i]·b[j]=βₖ where k=(i div 2³)+2^{m-j-l} (1)

since k=(i+2^{m-1}) div 2^{J}=(i div 2^{J})+2^{m-J-l.}

The reason for enumerating the bits in the overlapped memory is to define their interdependencies, i.e. in which registers and where in these registers does a certain bit appear. In real implementation the registers are words in a processor memory space— they are read and written as words at any other memory location.

This brings us to a formal description of how the split tagged tree is stored in the memory:

Definition 7: The memory representation of a split tagged tree from Definition 4 in Algorithm 1 consists of four variables residing in two parts of memory:

reg: overlapped registers storing internal nodes of the tree (see eq. (1)). Bit β₁ is set iff node n₁ is tagged. These registers reside in the overlapped memory.

elt: leaves of the tree, where bit elt[e] is set, iff leaf e is tagged.

internal: internal node pointers to the largest element in the left subtree and to the smallest element in the right subtree of a given node. Pointers internalt [i] correspond to node n_{1.}

leaf: ordered doubly linked list of elements of N.

Algorithm 1: Memory representation of a split tagged tree
(data structure) used for the dynamic neighbourhood problem

| | |
|---|---|
| CONST M = 2^{m}; | (* size of universe M *) |
| VAR | (* BINARY TREE OF TAGS: *) |
| reg. ARRAY [0 . . . M/2-1] OF WORD IN Yggdrasil; | (* internal nodes and *) |
| elt. ARRAY [0 . . . M-1] OF BOOLEAN IN Conventional, | (* leaves *) |
| | (* POINTERS *) |
| internal: ARRAY [1 . . . M-1] OF RECORD | (* at internal nodes point to *) |
| left, | (* the largest element In the left subtree and *) |
| right: WORD; | (* the smallest element in the right subtree, and *) |
| END IN Conventional; | |
| leaf ARRAY [0 . . . M-1] OF RECORD | (* at leaves *) |
| prev, next WORD; | (* connect elements of N in a doubly linked list *) |
| END IN Conventional, | |

The size of this data structure is dominated by the arrays of pointers and remains Θ (M log M) bits. We will reduce it later.

To find the neighbours of e, by Lemma 2 we need only find e's lowest left and right splitting nodes. By Definition 7 the register reg[e DIV 2] represents the path from the leaf e to the root and the set bits in the register correspond to splitting nodes. Therefore, we must separate those bits representing left internal nodes from those representing right internal nodes, and find the least significant set bit among each.

To separate the bits consider a path from the leaf e to the root and the i^{th} level node nₖ on this path. It is not hard to see that if e.b[i]=0, where k=(e div 2ⁱ)+2^{m-1-1} (cf. eq. (1)), then element e is in the left subtree of nₖ and otherwise it is in the right subtree of nₖ. In other words, the element e itself is a mask that can be used to separate bits representing left and right internal splitting nodes, and hence expressions

reg[e DIV 2]Λ e and reg[e DIV 2]Λ NOT (e) (2)

extract bits representing e's right and left splitting nodes respectively. We can use such simple expressions only because we put the root of the tree in the most significant position of the overlapped registers reg[.]. Now it is easy to prove:

Lemma 3: Given an element e ε M we can compute its lowest left and right splitting nodes in constant time.

Proof: After separating biats by eq. (2) we compute the least significant set bit.

We also require the lowest common node of elements e and f:

Lenma 4: The lowest common node of two elements can be computed in constant time.

Proof: The lowest common node of elements e and f is the last common node in the paths from the root to e and f. Therefore, the most significant set bit of exclusive or of e and f corresponds to the node immediately below the lowest common node. Algorithm 3 presents the details of the calculation.

The operations required for the dynamic closest neighbour problem will be implemented in the following. We use the data structure of Definition 7. All implementations find both closes neighbours of e ε U in N. From the preceding discussion and Algorithm 4, we easily see by Algorithm 5:

Lemma 5: The left and the right neighbours of e in N can be
found in constant time.
Algorithm 2: The lowest left and right splitting nodes of e.

| | |
|---|---|
| PROCEDURE LowestSplittingNodes (e), | |
| tmp: = e DIV 2, path: = reg[tmp]; | (* The path from e to the root, *) |
| j: = LMB (path AND Negate (e)); | (* the least significant set bit by eq. (2), *) |
| n₁ = (tmp DIV 2^{j}) + 2^{m-1-3}; | (* and the corresponding node by eq. (1). *) |
| j. = LMB (path AND e); | (* Similarly, the lowest right splitting node *) |
| nᵣ: = (tmp DIV 2^{j}) + 2^{m 1 j}, | |
| RETURN (n₁, nᵣ) | |
| END LowestSplittingNodes; | |

Algorithm 3: The lowest common node of e and f, and an ap-
pearance of a corresponding bit in overlapped registers.

| | |
|---|---|
| PROCEDURE LowestCommon Node (e, f), | |
| j: = LMB (E XOR f) + 1; | (* The appearance of bit in a register, *) |
| n₂: = (e DIV 2³⁺¹) + 2^{m 1-j}; | (* and corresponding node by eq. (1). *) |
| RETURN (nⱼ, j) | |
| END LowestCommonNode, | |

Algorithm 4: The neighbours of e ε U in N.

| | |
|---|---|
| PROCEDURE Neighbours (e); | |
| IF elt[e] THEN | (* if e ε N we can use a double linked list. *) |
| RETURN leaf [e] | |
| ELSE (n₁, nᵣ): = LowestSplittingNodes (e), | (* Otherwise pointers at one *) |
| IF Between (internal [n₁], e) THEN | (* of the lowest splitting nodes *) |
| RETURN internal [n₁] | (* point to both neighbours. *) |
| ELSE RETURN internal [nᵣ] END | |
| END | |
| END Neighbours; | |

Algorithm 5: Searching for the left and the right neighbour
of e in N.

PROCEDURE Left (e);
(left, right): = Neighbours (e);
RETURN left;
END Left;
PROCEDURE Right (e);
(left, right) = Neighbours (e);
RETURN right;
END Right;

Algorithm 7: Deletion of e from N.

| | |
|---|---|
| PROCEDURE Delete (e); | |
| (n₁, nᵣ): = LowestSplittingNodes (e); | |
| | (* UPDATE LEAVES *) |
| (x, y) = Neighbours (e). | (* Find both neighbours, *) |
| leaf[x] next- = y, leaf[y].prev- = x, | (* delete e from a double linked and *) |
| elt[e]: = FALSE; | (* take a tag off a proper leaf. *) |
| | (* UPDATE THE TREE: *) |
| IF n₁ > n₂ THEN | (* The lowest splitting nodes *) |
| (tmp, bit): = LowestCommonNode (x, e); higher: = n₁ | |
| ELSE (tmp, bit). = LowestCommonNode (e, y), higher = nᵣ | |
| END; | (* are treated differently *) |
| reg[e DIV 2].b[bit]: = FALSE; | (* the lower is no longer a splitting node and *) |
| internal[higher].left: = x; | (* the higher gets pointers *) |
| internal[higher]right: = y; | (* to both neighbours. *) |
| END Delete, | |

FIG. 6 is helpful in describing the insert and delete operations. It shows the effect of inserting e into the corresponding diagrams of FIG. 4. Now, to insert:

Lemma 6: Updates necessary for an insertion can be performed in constant time.

Proof: Let x and y be the left and right neighbours of e (e ∉ N), which is to be inserted. We prove that Algorithm 6 properly inserts e into N maintaining the split tagged tree of Definition 4. First, the algorithm tags the proper leaf and inserts it in a doubly linked list, so the second and third parts of Definition 4 are satisfied.

By a simple counting argument, it is easy to see that if we insert one element, exactly one internal node in a split tagged tree becomes a splitting node. Without loss of generality assume nᵣ is the lowest right splitting node of e, n is the lowest common node of e and y, and n is lower than the lowest common node of x and e. To prove that Algorithm 6 also maintains the first part of Definition 4, we have to show that after the insertion n becomes a splitting node (it gets tagged) and that the pointers at e's lowest left and right splitting nodes are properly updated,

As n is the lowest common node of e and y, these elements are in its left and right subtrees respectively (cf. left diagram in FIG. 4) . Hence, n is a splitting node after the insertion. If n were a splitting node before the insertion, there would be at least one element, z, in the left subtree of n. Hence, either x<z<e or e<z<y, which contradicts the initial assumption about eas neighbours. Moreover, after the insertion e is the only element in the left subtree of n₁ and so n is also e's lowest left splitting node, while nᵣ remains its lowest right splitting node. Algorithm 6 properly updates pointers at both nodes, while Lemma 2 guarantees that no other pointers need be changed. Constant run time follows from Algorithm 3 and Algorithm 4.

Finally, we deal with a deletion:

Lemma 7: An element can be deleted from N in constant time.

Proof: Algorithm 7 takes constant time. Assuming e ε N, its correctness follows from Lemma 2 by similar reasoning to the proof of Lemma 6.

We conclude the section by:

Theorem 1: Using the data structure described above, the one-dimensional dynamic closest neighbour problem on a universe of size M can be solved in constant time and O(M log M) bits of space.

Proof: The space bound follows from the data structure described in Definition 7, and the time bound from Lemma 5, Lemma 6, and Lemma 7.

C. Memory Implementation

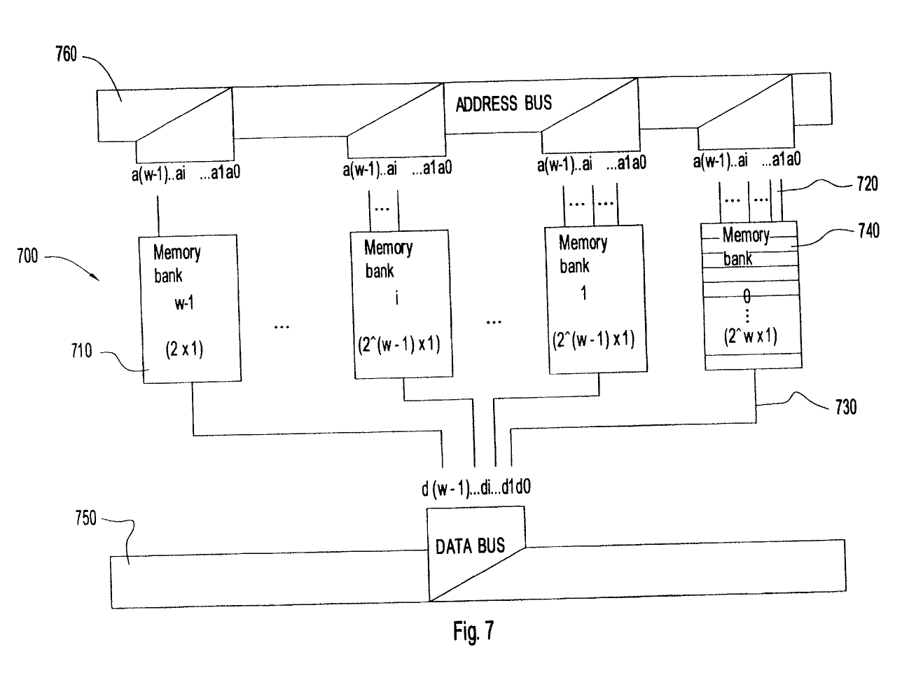

It turns out that the most difficult problem in the maintenance of the data structure for the problem of finding the closest neighbour to the left and/or to the right is to distribute information about the changes throughout the data structure quickly enough. The problem is solved by designing a special memory 700 according to FIG. 7, which permits that a change in a single memory location is reflected in many other memory locations.

The role of the memory 700 is to return on the data bus 750 the content of the memory location at the address put on the address bus 760; or to write the value put on the data bus into the memory location at the address put on the address bus.

In detail, let our memory locations be w bits wide and let our memory consist of w memory banks 710. When we put on the address bus 760 an address a, we get from the first bank the first (least significant) bit of the memory location a, from the second bank the second bit of the memory location a, from the third bank the third bit and so on. Similarly, when we write into the memory.

Each bank is in fact a 1-bit wide memory. More precisely, the i-th bank is a 1-bit wide memory with 2(w-i) bank-memory locations 740, (w-d) address inputs 720 and one data output 730. So, when the address a appears on the address bus, its (w-i) most significant bits are used in the bank i to retrieve the 1-bit value of the bank-memory location. The writing works similarly.

From the above description, it is also obvious that our memory is easier to manufacture than the conventional memory, because all banks (bits) do not require all address lines, which simplifies the address decoders.

D. Alternative Embodiments and Improvements

The doubly linked list leaf is used only to find neighbours when e ε N. In this case, by Lemma 2, the pointers to e's neighbours are located in its lowest splitting nodes, and so, by Lemma 3, they can be computed in constant time and we can dispense with the doubly linked list.

The bit array elt stores tags at leaves of a binary tree. A leaf has a tag iff the corresponding element is in N. However, by Lemma 2, e ε N iff one of the pointers at its lowest splitting node refers back to e. By Lemma 3 the lowest splitting node can be computed in constant time, so the array elt is redundant.

Next, we reexamine internal, the array of m-bit pointers at the internal nodes. These references are to descendents of the nodes in question. Hence, the pointers need only indicate the path from the internal node itself to the relevant leaf. If the internal node is i levels above the leaves, this takes i bits. Moreover, it takes only i-1 bits, since the value of the i^{th} bit of the pointer to the largest (smallest) element in the left (right) subtree is 0 (1). To summarize, from the data structure in Definition 7, we are left with overlapped registers reg, for a tree of tags, and an array of variable length pointers internal.

The simplification of the data structure not only improves the space bound, but also the running time of the algorithms, as they need not maintain leaves, elt, and a doubly linked list leaf, at these leaves.

A further saving in space is achieved by splitting the universe into buckets of m consecutive elements and representing each bucket by a bit map. The insertion and deletion in a bit map are trivial. Treating buckets as elements of a smaller M/m-element universe (a bucket-element is present iff at least one of its elements is present), we build the split tagged tree structure as described above. The bit maps require M bits, and the tree on the top only 3M/m+0(m) bits. The second application of this bucketing trick reduces the space requirement to M+M/m+3M/m2+0(m) bits and so:

Theorem 2: Using the above data structure, the one-dimensional dynamic closest neighbour problem on the universe of size M can be supported in constant time using space M+M/lgM+o(M/lgM) bits.

In some applications the only neighbour we are ever looking for is either the left or the right one. According to a further embodiment, this changes the definition of the problem from Definition 1; the insertion and deletion operations are still supported, but instead of supporting both Right and Left, we support only one of them. In particular, for an efficient implementation of the priority queue, it is sufficient to support the search for the right neighbour only (cf. Table 2).

As we will show, the support for search of only one neighbour further simplifies the data structure and hence speeds up the algorithm. Moreover, the support for deletion and search of the extreme element only even further simplifies the algorithms. The later problem is particularly important as it gives the direct solution of the priority queue problem.

Below, we will discuss the search for the right neighbour problem, but with an appropriate change the same solution can be used to search for the left neighbour.

We are still using the split tagged tree from Definition 4, though slightly changed:

ad(i.) with each splitting node is associated only information about the smallest node in the right subtree;

ad(ii.) leaves are not stored;

ad(iii.) the doubly linked list does not exist.

This gives us the following data structure (cf. Definition 7 and Algorithm 1:

CONST M=2\hat{ }m; { size of universe }
VAR

{ binary tree of tags: }

reg: ARRAY [0 . .M/2−l] OF WORD IN Overlapped;

{ the smallest element in the right subtree}

right: ARRAY [1 . .M−1] OF WORD IN Conventional;

where the “right” pointers can be of variable length— decreasing from the top to the bottom— if we want to save on space. This, however, increases the access time.

The search procedure works similarly as before (cf. Algorithm 4), only we do not zest on being between the neighbours, but only which of the two possible candidates is to the right. The right neighbour of e is an element:

that is to the right of e and

is pointed to either by the pointer at the lowest left splitting node of e or by the pointer at the lowest right splitting node of e.

If we want to support only the search for the left-most element in the set, we store pointer nₘᵢₙ to this element separately.

When determining a right neighbour of an element e in the subset N of the digital memory structure described above, these steps may be carried out: evaluating register reg[e div 2] for determining the lowest left splitting node p₁ of e; and if p₁ exist, returning the pointers in internal f[p] (otherwise no right neighbour exists)

The insertion and deletion are similar to the procedures before (cf. Algorithms 6 and 7), though slightly simpler:

For the general insertion, we need to find only the lowest right splitting node of e, n. Let Yᵣ be the element pointed to by the pointer at nᵣ. First, a new splitting node is created at the lowest common node of e and Yᵣ; n. Next, if Yᵣ is also the right neighbour of e, we update pointer at nᵣ to point to e and the pointer at n to point at Yᵣ; otherwise we only update the pointer at n to point at e. The special case, when e is the smallest element, is treated separately.

Hence, an element e may be inserted into the subset N of the digital memory structure by: evaluating register reg[e div 2] for determining the lowest right splitting node pᵣ of e; letting Yᵣ be the element pointed to by Pᵣ; determining a lowest common node q of element e and Yᵣ; marking node q as tagged in register reg[e div 2]; and updating pointers internal for nodes related to element e.

A general deletion is achieved in the following way. Find both the lowest left and the lowest right splitting nodes. If the right is lower, mark it as not tagged and we are done. If not, update the pointer in the lowest right splitting node to point to the element now pointed to by the lowest left splitting node. Mark the lowest left splitting node as not tagged and we are done.

Hence, an element e may be deleted from the subset N of the digital memory structure by: evaluating register reg[e div 2] for determining the lowest left and lowest right splitting node p₁ and p₁, respectively, of e; marking the lower of p₁ and pᵣ as not tagged in register reg[e div 2]; and updating pointers internal for nodes related to element e.

In the previous section, a hardware implementation of a binary tree has been described, storing one bit in each node of the tree. It is clear that by using other than consecutive numbers 1, 2, 3 . . . w as the number of address inputs, we could instead use any other sequence of numbers giving other output degrees of the tree, which all are a power of two. Furthermore, it can be of great value to have more than one memory bank with the same address inputs, since this will make it possible to store more than one bit in each node. In particular, by having one bank for all the leaves, two for the parents of the leaves, three for the next ones and so on, we could store the entire tree, including the pointers in the array internal, in the special memory. This will have the effect that we only have to make one memory access to get all of this information. The drawback of this solution is that we can not have the same number of priority levels for the tree.

Another application of using multiple banks with the same input addresses is to have several banks for the leaves. These can be used to store data associated with each leave. Again, data will then also be retrieved with one memory access.

1. A digital memory device (700) comprising a plurality of memory banks (710), each memory bank having a predetermined number of address input(s) (720), at least one data output (730) and a plurality of memory locations (740) arranged to store a respective digital value, characterized in that
at least two of the memory banks (710) have a mutually different number of memory locations (740) and/or address inputs (720).

2. A digital memory device (700) according to claim 1 for storing w-bit digital words, each memory bank representing a respective bit position i, where 0<i<w-1, in the digital words, characterized in that
each respective memory bank (710) has 2^{(w-1)} memory locations (740) and (w-i) address inputs (720).

3. The use of a digital memory device (700) according to claim 1 or 2 for handling a dynamic closest neighbour problem, a priority queue or a union-split-find problem.

4. A digital memory structure for managing a subse N of a universe U={O . . . . M-1} of elements e, the universe U being represented by a complete binary tree of height m+1 with elements e of the universe U at its leaves, characterized by:
an array of overlapped registers reg[i], preferably where 0≦i ≦M/2-1, for storing internal nodes of the binary tree along respective paths from ancestors of said leaves to root, wherein location j of register reg[i] is arranged to store internal node k, preferably where k=(i div 2^{J})+2^{m-J-1}, and wherein any internal node of the binary tree is stored as tagged, if the right and/or the left subtree thereof contain(s) at least one element of subset N; and
an array of pointers internal[1], preferably where 1 ≦1≦M-1, to the smallest element in the right subtree, and/or the largest element in the left subtree, of each respective internal node 1.

5. A digital memory structure as in claim 4, further comprising an array of values elt[n], where 0≦n≦M-1, for representing the leaves of the binary tree, wherein elton[n] is set to a first value, if leaf n is an element of subset N, and it otherwise set to a second value.

6. A digital memory structure as in claim 4 or 5, further comprising a doubly linked list leaf of elements of.

7. A method of determining a left and a right neighbour of an element e in the subset N of the digital memory structure according to any of claims 4-6, comprising the steps of:
a) evaluating register reg[e div 2] for determining such internal nodes p₁ and pᵣ, the left and the right subtree of which contain element e;
b) returning internal [pᵣ] left and internal[p₁] right, if either pointer in the lower of the two nodes P₁ and pᵣ points to e; and otherwise
c) returning either pointers internal [p₁] or pointers internal [Pᵣ].

8. A method of inserting an element e in the subset N of the digital memory structure according to any of claims 4-6, comprising the steps of:
applying the method of claim 4 for determining the neighbours of element e;
determining a lowest common node q of element e and its left and/or right neigbour, respectively;
marking node q as tagged in register reg [e div 2]; and
updating pointers internal for nodes related to element e.

9. A method of deleting an element e from the subset N of the digital memory structure according to any of claims 4-6, comprising the steps of:
applying the method of claim 4 for determining the neighbours of element e;
determining a lowest common node q of element e and its left and/or right neigbour, respectively;
marking node g as not tagged in register reg [e div 2]; and
updating pointers internal for nodes related to element e.

10. A method of determining a right neighbour of an element e in the subset N of the digital memory structure according to any of claims 4-6, comprising the step of:
evaluating register reg [e div 2] for determining the lowest splitting node P₁ of e; and
if P₁ exists, returning the pointers in internal[p₁].

11. A method of inserting an element e in the subset N of the digital memory structure according to any of claims 4-6, comprising the step of:
evaluating register reg[e div 2] for determining the lowest right splitting node pᵣ of e;
determining a lowest common node q of element e and the element pointed to by p_{r;}
marking node q as tagged in register reg[e div 2]; and
updating pointers internal for nodes related to element e.

12. A method of deleting an element e from the subset N of the digital memory structure according to any of claims 4-6, comprising the step of:
evaluating register reg[e div 2] for determining the lowest left and lowest right splitting node p₁ and p₁ respectively, of e;
marking the lower of p₁ and pᵣ as not tagged in register reg[e div 2]; and
updating pointers internal for nodes related to element e.

13. The use of a digital memory structure according to any of claims 4-6 for handling a dynamic closest neighbour problem.

14. The use of a digital memory structure according to any of claims 4-6 for handling a priority queue.

15. The use of a digital memory structure according to any of claims 4-6 for handling a union-split-find problem.

16. A digital memory device (700) according to claim 1 or 2, containing in its memory banks (710) a digital memory structure according to any of claims 4-6.
